(19) United States
(12) Patent Application Publication
(10) Pub. No.: US 2024/0235506 A1
(43) Pub. Date: Jul. 11, 2024

(54) FILTER CALIBRATION FOR RECEIVER

(71) Applicant: Atmosic Technologies, Inc., Campbell, CA (US)

(72) Inventors: Bita Nezamfar, Los Altos, CA (US); Manolis Terrovitis, Athens (GR); Justin Ann-Ping Hwang, Sunnyvale, CA (US)

(73) Assignee: Atmosic Technologies, Inc., Campbell, CA (US)

(21) Appl. No.: 18/403,277

(22) Filed: Jan. 3, 2024

Related U.S. Application Data
(60) Provisional application No. 63/437,192, filed on Jan. 5, 2023.

(51) Int. Cl. H03F 3/45; H04B 1/10

(52) U.S. Cl. CPC H03F 3/45973; H03F 3/45475; H04B 1/1036; H03F 2200/372; H03F 2200/451

(57) ABSTRACT

Methods and apparatus for baseband receiver circuits are disclosed. An example receiver circuit includes a first amplifier stage to receive input signals and generate intermediate signals responsive to the one or more input signals and based at least in part on one or more amplifiers, one or more capacitors, and one or more resistors of the first amplifier stage, a second amplifier stage to receive the intermediate signals and generate output signals responsive to the one or more intermediate signals based at least in part on one or more amplifiers, one or more capacitors, and one or more resistors of the second amplifier stage, and calibration logic configured to disconnect the first amplifier stage from the second amplifier stage, inject one or more first signals into at least the first amplifier stage and calibrate at least the first amplifier stage based at least in part on a frequency response of the first amplifier stage to the injected one or more first signals.

### CROSS-REFERENCE TO RELATED APPLICATIONS

This Patent Application claims priority to U.S. Provisional Patent Application No. 63/437,192 entitled “FILTER CALIBRATION FOR RECEIVER” and filed on Jan. 5, 2023, which is assigned to the assignee hereof. The disclosures of all prior Applications are considered part of and are incorporated by reference in this Patent Application.

### TECHNICAL FIELD

This disclosure relates generally to circuits and techniques for filter calibration, and more specifically to calibration of filters within receivers.

### BACKGROUND OF RELATED ART

Communication devices typically include receiver circuits. For example, a communication device may include one or more receiver circuits, such as a baseband receiver circuit, for processing communication signals. Some receiver circuits may operate on quadrature signals, such as signals including an in-phase or I component, and a quadrature phase or Q component, such that the Q component signals have the same frequency and amplitude as the I component signals but are shifted in phase by a quarter wavelength. Receiver circuits may include amplifiers such as differential amplifiers. For receivers including differential amplifiers and which operate on quadrature signals, the I component signals may each include a first I component signal and a second I component signal, where the first I component signal is complementary to the second I component signal, and vice versa. Similarly, the Q component signals may each include a first Q component signal and a second Q component signal, where the first Q component signal is complementary to the second Q component signal, and vice versa.

Values of chip components within such receiver circuits may vary, such as values of capacitors, resistors, and so on. Consequently, such receiver circuits require calibration, such as adjustment of capacitance and resistance values within the receiver circuit, to compensate for such variation. Such calibration may ensure proper functionality and compensate for non-idealities in the receiver circuit.

### SUMMARY

This Summary is provided to introduce in a simplified form a selection of concepts that are further described below in the Detailed Description. This Summary is not intended to identify key features or essential features of the claimed subject matter, nor is it intended to limit the scope of the claimed subject matter. Moreover, the systems, methods, and devices of this disclosure each have several innovative aspects, no single one of which is solely responsible for the desirable attributes disclosed herein.

One innovative aspect of the subject matter described in this disclosure can be implemented as a receiver circuit. An example receiver circuit may include a first amplifier stage to receive input signals and generate intermediate signals based at least in part on one or more amplifiers, one or more capacitors, and one or more resistors of the first amplifier stage, a second amplifier stage to receive the intermediate signals and generate output signals based at least in part on one or more amplifiers, one or more capacitors, and one or more resistors of the second amplifier stage, and calibration logic configured to disconnect the first amplifier stage from the second amplifier stage, inject one or more first signals into at least the first amplifier stage and calibrate at least the first amplifier stage based at least in part on a frequency response of the first amplifier stage to the injected one or more first signals.

In some aspects, the first amplifier stage includes a first fully differential amplifier and a second fully differential amplifier, the first fully differential amplifier including a first input terminal, a second input terminal, a first output terminal, and a second output terminal, and the second fully differential amplifier comprising a third input terminal, a fourth input terminal, a third output terminal, and a fourth output terminal. In some aspects the first input terminal is coupled to the third output terminal via a first variable resistor, the second input terminal is coupled to the fourth output terminal via a second variable resistor; the third input terminal is coupled to the first output terminal via a third variable resistor, and the fourth input terminal is coupled to the second output terminal via a fourth variable resistor.

In some aspects, the first input terminal is coupled to the first output terminal via a first capacitor, the second input terminal is coupled to the second output terminal via a second capacitor, the third input terminal is coupled to the third output terminal via a third capacitor, and the fourth input terminal is coupled to the fourth output terminal via a fourth capacitor.

In some aspects, the first input terminal is coupled to the first output terminal via a fifth variable resistor, the second input terminal is coupled to the second output terminal via a sixth variable resistor, the third input terminal is coupled to the third output terminal via a seventh variable resistor, and the fourth input terminal is coupled to the fourth output terminal via an eighth variable resistor.

In some aspects, the calibration logic is further configured to decouple the fifth variable resistor from the first input terminal, decouple the sixth variable resistor from the second input terminal, decouple the seventh variable resistor from the third input terminal, and decouple the eighth variable resistor from the fourth input terminal.

In some aspects, the one or more first signals include a first pair of stimulus inputs injected into the first and second input terminals, and a second pair of stimulus inputs injected into the third and the fourth input terminals, where each stimulus input of the first pair and the second pair of stimulus inputs includes a single pulse.

In some aspects, the first amplifier stage includes a transimpedance amplifier (TIA) stage, and the second amplifier stage includes a programmable gain amplifier (PGA) stage.

In some aspects, the first amplifier stage is coupled to the second amplifier stage via one or more notch filters configured to attenuate signals at one or more signals associated with a sampling rate of one or more analog to digital converters (ADCs) coupled to the one or more output signals.

In some aspects, the second amplifier stage includes a third fully differential amplifier and a fourth fully differential amplifier, the third fully differential amplifier including a fifth input terminal, a sixth input terminal, a fifth output terminal, and a sixth output terminal, and the fourth fully differential amplifier including a seventh input terminal, an eighth input terminal, a seventh output terminal, and an eighth output terminal, where the fifth input terminal is coupled to the seventh output terminal via a ninth variable resistor, the sixth input terminal is coupled to the eighth output terminal via a tenth variable resistor; the seventh input terminal is coupled to the fifth output terminal via an eleventh variable resistor, and the eighth input terminal is coupled to the sixth output terminal via a twelfth variable resistor.

In some aspects, the fifth input terminal is coupled to the fifth output terminal via a fifth capacitor, the sixth input terminal is coupled to the sixth output terminal via a sixth capacitor, the seventh input terminal is coupled to the seventh output terminal via a seventh capacitor, and the eighth input terminal is coupled to the eighth output terminal via an eighth capacitor.

In some aspects, the fifth input terminal is coupled to the fifth output terminal via a thirteenth variable resistor, the sixth input terminal is coupled to the sixth output terminal via a fourteenth variable resistor, the seventh input terminal is coupled to the seventh output terminal via a fifteenth variable resistor, and the eighth input terminal is coupled to the eighth output terminal via a sixteenth variable resistor.

In some aspects, the calibration logic is further configured to decouple the thirteenth variable resistor from the fifth input terminal, decouple the fourteenth variable resistor from the sixth input terminal, decouple the fifteenth variable resistor from the seventh input terminal, and decouple the sixteenth variable resistor from the eighth input terminal.

In some aspects, the one or more first signals include a third pair of oscillating inputs injected into the fifth and sixth input terminals, and a fourth pair of oscillating inputs injected into the seventh and the eighth input terminals, where each oscillating input of the third pair and the fourth pair of oscillating inputs includes a single pulse.

In some aspects, the calibration logic is configured to adjust the values of the one or more resistors and one or more capacitors of the first amplifier stage so that the frequency response of the first amplifier stage to the injected one or more first signals matches a first predefined frequency response, the first predefined frequency response indicating that the first amplifier stage is properly calibrated.

In some aspects, at least one of the one or more first signals are injected into the second amplifier stage, and wherein the calibration logic is further configured to adjust values of one or more resistors and one or more capacitors of the second amplifier stage so that the frequency response of the second amplifier stage to the injected at least one of the one or more first signals matches a second predefined frequency response, the second predefined frequency response indicating that the second amplifier stage is properly calibrated.

Another innovative aspect of the subject matter described in this disclosure can be implemented as a method for calibrating a baseband receiver. An example method includes disconnecting a first amplifier circuit of the baseband receiver from a second amplifier circuit of the baseband receiver, the first amplifier circuit coupled in series to the second amplifier circuit, disconnecting one or more resistors of the first amplifier circuit, injecting one or more first signals into the first amplifier circuit, and tuning values of one or more variable resistors and one or more variable capacitors of the first amplifier circuit such that a frequency response of the first amplifier circuit in response to the injected one or more first signals matches a first predetermined frequency response.

Another innovative aspect of the subject matter described in this disclosure can be implemented as a baseband receiver. An example baseband receiver includes a first amplifier stage including a first fully differential amplifier and a second fully differential amplifier, a second amplifier stage coupled in series with the first amplifier stage, and calibration logic for calibrating the first amplifier stage, the calibration logic configured to inject one or more first signals into inputs of the first amplifier stage and adjusting values of variable resistors and variable capacitors such that a frequency response of the first amplifier stage in response to the injected one or more first signals matches a first predetermined frequency response. Each input of the first fully differential amplifier is coupled to a respective output of a second fully differential amplifier via a corresponding first crossover variable resistor, and each input of the second fully differential amplifier is coupled to a respective output of the first fully differential amplifier via a corresponding second crossover variable resistor. Each input of the first fully differential amplifier is coupled to a respective output of the first fully differential amplifier via a corresponding first feedback variable resistor and via a corresponding first feedback variable capacitor, and each input of the second fully differential amplifier is coupled to a respective output of the second fully differential amplifier via a corresponding second feedback variable resistor and via a corresponding second feedback variable capacitor. The variable resistors and variable capacitors include the first crossover variable resistors, second crossover variable resistors, first feedback variable resistors, second feedback variable resistors, first feedback variable capacitors, and second feedback variable capacitors.

### BRIEF DESCRIPTION OF THE DRAWINGS

The present embodiments are illustrated by way of example and are not intended to be limited by the figures of the accompanying drawings.

FIG. 1 shows a block diagram of a receiver circuit which may be used with the example implementations.

FIG. 2A shows an example baseband filter which may be used with the example implementations.

FIG. 2B shows an example baseband filter, representing the baseband filter of FIG. 2A when configured for calibration in accordance with the example implementations.

FIG. 3 shows an illustrative flow chart depicting an example operation for calibrating a baseband receiver, according to some implementations.

### DETAILED DESCRIPTION

In the following description, numerous specific details are set forth such as examples of specific components, circuits, and processes to provide a thorough understanding of the present disclosure. The term “coupled” as used herein means connected directly to or connected through one or more intervening components or circuits. The terms “electronic system” and “electronic device” may be used interchangeably to refer to any system capable of electronically processing information. Also, in the following description and for purposes of explanation, specific nomenclature is set forth to provide a thorough understanding of the aspects of the disclosure. However, it will be apparent to one skilled in the art that these specific details may not be required to practice the example implementations. In other instances, well-known circuits and devices are shown in block diagram form to avoid obscuring the present disclosure. Some portions of the detailed descriptions which follow are presented in terms of procedures, logic blocks, processing and other symbolic representations of operations on data bits within a computer memory.

These descriptions and representations are the means used by those skilled in the data processing arts to most effectively convey the substance of their work to others skilled in the art. In the present disclosure, a procedure, logic block, process, or the like, is conceived to be a self-consistent sequence of steps or instructions leading to a desired result. The steps are those requiring physical manipulations of physical quantities. Usually, although not necessarily, these quantities take the form of electrical or magnetic signals capable of being stored, transferred, combined, compared, and otherwise manipulated in a computer system. It should be borne in mind, however, that all of these and similar terms are to be associated with the appropriate physical quantities and are merely convenient labels applied to these quantities.

Unless specifically stated otherwise as apparent from the following discussions, it is appreciated that throughout the present disclosure, discussions utilizing the terms such as “accessing,” “receiving,” “sending,” “using,” “selecting,” “determining,” “normalizing,” “multiplying,” “averaging,” “monitoring,” “comparing,” “applying,” “updating,” “measuring,” “deriving” or the like, refer to the actions and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

In the figures, a single block may be described as performing a function or functions; however, in actual practice, the function or functions performed by that block may be performed in a single component or across multiple components, and/or may be performed using hardware, using software, or using a combination of hardware and software. To clearly illustrate this interchangeability of hardware and software, various illustrative components, blocks, modules, circuits, and steps have been described below generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure. Also, the example input devices may include components other than those shown, including well-known components such as a processor, memory and the like.

The techniques described herein may be implemented in hardware, software, firmware, or any combination thereof, unless specifically described as being implemented in a specific manner. Any features described as modules or components may also be implemented together in an integrated logic device or separately as discrete but interoperable logic devices. If implemented in software, the techniques may be realized at least in part by a non-transitory processor-readable storage medium comprising instructions that, when executed, performs one or more of the methods described above. The non-transitory processor-readable data storage medium may form part of a computer program product, which may include packaging materials.

Various implementations relate generally to the calibration of receiver circuits in wireless communication devices. In some implementations, a receiver circuit may be calibrated by injecting oscillating signals into portions of the receiver circuit and the capacitors and resistors of the receiver circuit may be tuned so that a frequency response of a portion of the receiver circuit matches a predetermined frequency response. For example, the receiver circuit may include a first amplifier stage and a second amplifier stage, and during calibration the first amplifier stage may be disconnected from the second amplifier stage, and signals injected into the inputs of the first amplifier stage and the second amplifier stage. These injected signals cause oscillation in the first amplifier stage and the second amplifier stage. The first amplifier stage and the second amplifier stage may then be separately calibrated by adjusting values of their resistors and capacitors such that a frequency response of the first amplifier stage matches a first predetermined frequency response and a frequency response of the second amplifier stage matches a second predetermined frequency response.

Particular implementations of the subject matter described in this disclosure can be implemented to realize one or more of the following potential advantages. In some implementations, example receiver circuits may be calibrated without requiring the use of a process monitor as with conventional techniques. Such a process monitor may not be required for purposes other than calibration, and so example receiver circuits may be simplified by omitting this process monitor. Further, such conventional techniques may only calibrate resistor and capacitor values for a receiver circuit and may not account for non-idealities in the amplifiers of the receiver circuit. In contrast, example receiver circuits may be calibrated using the components of the receiver circuit and may therefore take into account amplifier non-idealities.

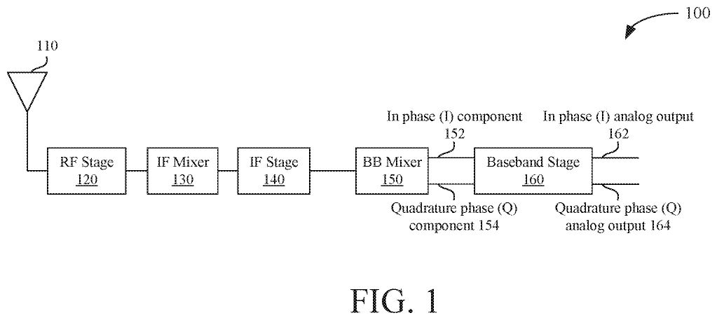

FIG. 1 shows a block diagram of a receiver circuit 100 which may be used with the example implementations. The receiver circuit 100 includes one or more antennas 110 for receiving radio frequency (RF signals). Note that while FIG. 1 shows the RF signals being received via the one or more antennas 110, that in some aspects, the RF signals may be received via a wired interface, such as coaxial cable, a fiberoptic cable, or similar. The receiver circuit also includes an RF stage 120 for processing radio frequency signals received via the one or more antennas 110. For example, the RF stage 120 may include one or more of a preselect filter, a low-noise amplifier (LNA), an image filter, and so on, configured for filtering and amplifying the received RF signals prior to their conversion to an intermediate frequency (IF). The receiver circuit 100 also includes an IF mixer 140 configured to shift the processed RF signals to the intermediate frequency, for example by mixing them with a signal from a local oscillator. The receiver circuit 100 may also include an IF stage 140 for processing the IF signals received from the IF mixer 130. For example, the IF stage 140 may include one or more filters, such as one or more bandpass filters to select signal components within a specific channel, one or more amplifier circuits, such as one or more variable gain amplifier (VGA) amplifier circuits.

The receiver circuit 100 may also include a baseband (BB) mixer 150, which may shift the IF signals to a baseband frequency, for example by mixing the IF signals with another local oscillator. For example, the IF stage 130 may shift the RF signals to the IF by mixing a carrier signal of the RF signals with a local oscillator signal. In some aspects, the BB mixer 150 may output quadrature signals, such as including an in-phase (I) component 152 and a quadrature phase (Q) component 154. As discussed above, the Q component 154 may have the same frequency and amplitude as the I component 152 but may be shifted by one quarter wavelength. In some aspects, not shown in FIG. 1 for simplicity, the BB mixer 150 may output a differential signal for each of the I component 152 and the Q component 154. For example, the I component signal 152 may include two signals, a noninverted I component signal and an inverted I component signal.

The baseband stage 160 may include one or more filters, such as a baseband filter, which may be a lowpass filter (LPF), one or more amplifiers, such as one or more transimpedance amplifiers (TIAs), one or more programmable gain amplifiers (PGAs), in addition to other components. The baseband stage 160 may output an I analog output 162 and a Q analog output 164, each of which may include a pair of differential signals. While not shown in FIG. 1 for simplicity, the outputs of the baseband stage 160 may be provided to one or more analog to digital converters (ADCs).

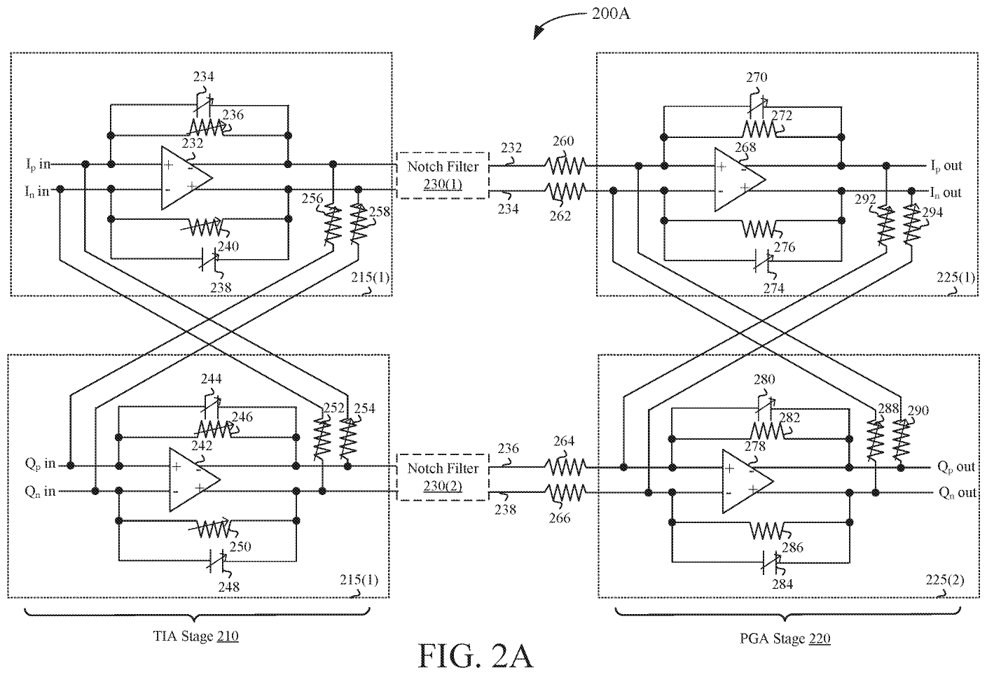

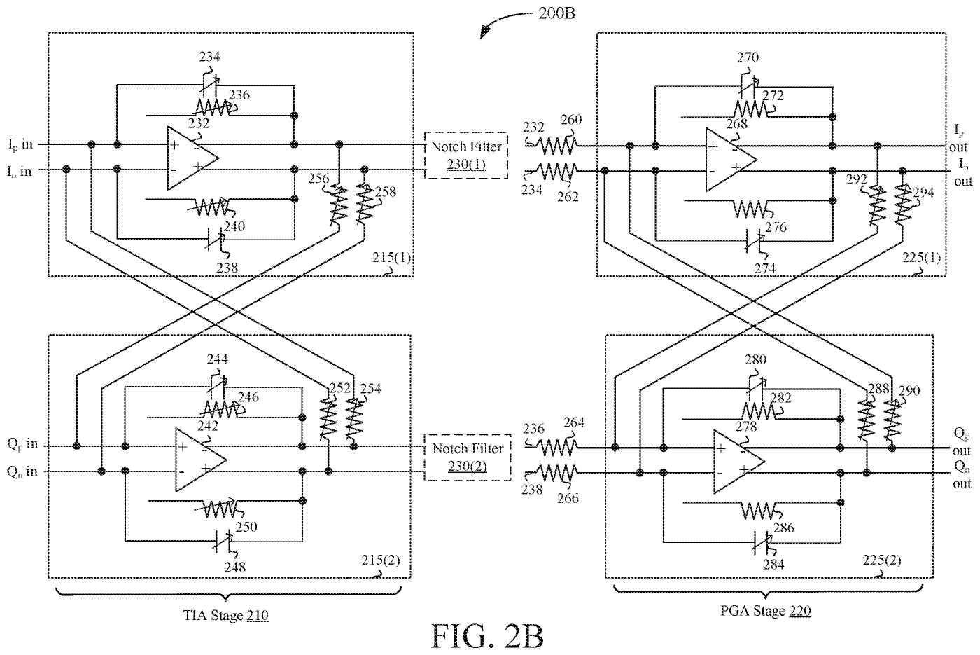

FIG. 2A shows an example baseband filter 200A which may be used with the example implementations. The baseband filter 200A may be part of the baseband stage 160 of FIG. 1. The baseband filter 200A is shown to include two stages, which may be referred to as a first amplifier stage and a second amplifier stage. The first amplifier stage may be a transimpedance amplifier (TIA) stage 210, and the second amplifier stage may be a programmable gain amplifier (PGA) stage 220. The TIA stage 210 and the PGA stage 220 may each operate on a pair of differential in-phase (I) signals and a pair of differential quadrature phase (Q) signals. Thus, the inputs of the baseband filter 200A are the differential pair of in-phase signals Iₚ in and Iₙ in and the differential pair of quadrature phase signals Qₚ in and Qₙ in. The outputs of the baseband filter 200 are the differential pair of in-phase signals Iₚ out and Iₙ out and the differential pair of quadrature phase signals Qₚ out and Qₙ out.

The TIA stage 210 and the PGA stage 220 may be coupled via resistors 260 and 262 and optionally a notch filter 230(1) for the in-phase signals and via resistors 264 and 266 and optionally notch filter 230(2) for the quadrature phase signals. The notch filter 230(1) may filter the in-phase outputs of the TIA stage 210, while the notch filter 230(2) may filter the quadrature phase outputs of the TIA stage 210. The notch filter 230(1) and the notch filter 230(2) (collectively the “notch filters 230”) may each be configured to filter frequencies which may interfere with downstream processing of the in-phase and quadrature phase signals processed by the baseband filter 200A. For example, the notch filters 230 may implement a notch filter configured to remove frequencies associated with sampling rates of one or more downstream ADCs. In some examples, a downstream ADC may operate at 16 MHZ, and the notch filters 230 may be configured to implement notch filters centered at this frequency, and having a relatively narrow bandwidth, such as 1-2 MHZ.

The TIA stage 210 and the PGA stage 220 may each receive a pair of differential in-phase (I) signals. More particularly, the TIA stage 210 may receive the differential pair of I signals Iₚ in and Iₙ in, and the PGA stage 220 may receive a differential pair of I signals 232 and 234. Similarly, the TIA stage 210 and the PGA stage 220 may each receive a pair of Q signals, and so the TIA stage 210 may receive the differential pair of Q signals Qₚ in and Qₙ in, while the PGA stage 220 receives a differential pair of Q signals 236 and 238.

The TIA stage 210 includes an amplifier circuit 215(1) and an amplifier circuit 215(2) whose inputs and outputs are cross coupled. That is, the inputs of the amplifier circuit 215(1) are coupled to the outputs of the amplifier circuit 215(2) and the inputs of the amplifier circuit 215(2) are coupled to the outputs of the amplifier circuit 215(1). More particularly, the amplifier circuit 215(1) includes a first fully differential amplifier 232 having a first input terminal, a second input terminal, a first output terminal, and a second output terminal, while the amplifier circuit 215(2) includes a second fully differential amplifier 242 having a third input terminal, a fourth input terminal, a third output terminal, and a fourth output terminal. The first input terminal is coupled to the third output terminal via a first variable resistor 254, and the second input terminal is coupled to the fourth output terminal via a second variable resistor 252. Similarly, the third input terminal is coupled to the first output terminal via a third variable resistor 256, and the fourth input terminal is coupled to the second output terminal via a fourth variable resistor 258.

Additionally, each input terminal of the first fully differential amplifier 232 is coupled to a corresponding output terminal of the first fully differential amplifier 232 via a variable resistor and a variable capacitor, and similarly each input terminal of the second fully differential amplifier 242 is coupled to a corresponding output terminal of the second fully differential amplifier 242 via a variable resistor and a variable capacitor. More particularly, the first input terminal is coupled to the first output terminal via a first variable capacitor 234 and a fifth variable resistor 236. Similarly, the second input terminal is coupled to the second output terminal via a second variable capacitor 238 and a sixth variable resistor 238. The third input terminal is coupled to the third output terminal via a third variable capacitor 244 and a seventh variable resistor 246, and the fourth input terminal is coupled to the fourth output terminal via a fourth variable capacitor 248 and an eighth variable resistor 250.

The PGA stage 220 includes an amplifier circuit 225(1) and an amplifier circuit 225(2) whose inputs and outputs are cross coupled. That is, the inputs of the amplifier circuit 225(1) are coupled to the outputs of the amplifier circuit 225(2) and the inputs of the amplifier circuit 225(2) are coupled to the outputs of the amplifier circuit 225(1). More particularly, the amplifier circuit 225(1) includes a third fully differential amplifier 268 having a fifth input terminal, a sixth input terminal, a fifth output terminal, and a sixth output terminal, while the amplifier circuit 225(2) includes a fourth fully differential amplifier 278 having a seventh input terminal, an eighth input terminal, a seventh output terminal, and an eighth output terminal. The fifth input terminal is coupled to the seventh output terminal via a ninth variable resistor 290, and the sixth input terminal is coupled to the eighth output terminal via a tenth variable resistor 288. Similarly, the seventh input terminal is coupled to the fifth output terminal via an eleventh variable resistor 292, and the eighth input terminal is coupled to the sixth output terminal via a twelfth variable resistor 294.

Additionally, each input terminal of the third fully differential amplifier 268 is coupled to a corresponding output terminal of the third fully differential amplifier 268 via a variable resistor and a variable capacitor, and similarly each input terminal of the fourth fully differential amplifier 278 is coupled to a corresponding output terminal of the fourth fully differential amplifier 278 via a variable resistor and a variable capacitor. More particularly, the fifth input terminal is coupled to the fifth output terminal via a fifth variable capacitor 270 and a thirteenth variable resistor 272. Similarly, the sixth input terminal is coupled to the sixth output terminal via a sixth variable capacitor 274 and a fourteenth variable resistor 276. The seventh input terminal is coupled to the seventh output terminal via a seventh variable capacitor 280 and a fifteenth variable resistor 282, and the eighth input terminal is coupled to the eighth output terminal via an eighth variable capacitor 284 and a sixteenth variable resistor 286.

As discussed above, conventional techniques for calibrating receiver filters, such as the baseband filter 200A or a filter of the baseband stage 160, may require the use of a process monitor. Such a process monitor may be coupled to the receiver filter and may for example be located on the same integrated circuit or “IC” as the receiver filter. The process monitor may calculate tuning values for capacitors and resistors of the receiver filter. For example, such a process monitor may be a separate circuit from the receiver filter and may include a plurality of resistors and capacitors. Conventional techniques may use such a process monitor to determine values for the resistors and capacitors of the receiver filter based on one or more measurements of the resistors and capacitors of the process monitor. However, such conventional techniques may fail to account for non-idealities in the operational amplifiers (“op amps) such as the fully differential amplifiers 232, 242, 268, and 178 of FIG. 2A. Because such non-idealities may significantly impact filter performance, it would be desirable to enable calibration which accounts for non-idealities in the op amps of the receiver filter, thus enabling more accurate calibration. Additionally, because conventional techniques use a separate circuit rather than the receiver circuit to be calibrated, any variation in the components of the process monitor versus the components of the receiver circuit will not be accounted for in calibration. Yet further, differences in the way the components are drawn on a chip between the process monitor and the receiver circuit may lead to differences not accounted for in conventional calibration techniques. Further, a process monitor may not be needed in the circuit for non-calibration purposes, and so enabling filter calibration without the use of a process monitor would enable simpler, more efficient, and more cost-effective filter circuits to be used for receiver filter circuits.

The example implementations may calibrate filters in receiver circuits without the use of a process monitor, and while accounting for non-idealities of the op amps in the circuits by operating stages of a receiver filter as an oscillator and adjusting values of resistors and capacitors in the receiver filter so that a frequency response a filter stage matches a predetermined frequency response indicating that the filter stage is properly calibrated. For example, for a two-stage filter the first stage may be separated from the second stage, and each stage may be separately calibrated in this manner.

In accordance with some implementations, the TIA stage 210 may be disconnected from the PGA stage 220 prior to calibration of the baseband filter 200A of FIG. 2A. FIG. 2B shows an example baseband filter 200B, representing the baseband filter 200A of FIG. 2A when configured for calibration in accordance with the example implementations. More particularly, the TIA stage 210 may be disconnected from the PGA stage 220 by disconnecting the notch filters 230(1) and 230(2) from respective resistors 260/262 and 264/266. Thus, inputs to the disconnected TIA stage 210 are still the pairs of differential inputs Iₚ in/Iₙ in and Qₚ in/Qₙ in, while inputs to the disconnected PGA stage are the pairs of differential signals 232/234 and 236/238. Further, the feedback variable resistors may also be disconnected when the baseband filter is configured for calibration. That is, the feedback variable resistors 236, 240, 246, 250, 272, 276, and 286 may be disconnected, as shown in FIG. 2B.

When calibrating the TIA stage 210, values of the crossover variable resistors 252, 254, 256, and 258 may be determined based on a bias resistance associated with the TIA stage 210. For example, in the PGA stage 220, the gain is a ratio of resistors, and so no calibration is required for the resistors. For the TIA stage 210, no input resistors are present (as compared with the PGA stage 220, where input resistors 260, 262, 264, and 266 are present), and the resistors of the PGA stage 220 may therefore be calibrated based on a bias resistance associated with the baseband filter 200A. Receiver circuits may commonly include circuits for such bias resistance calibration.

Next, signals may be provided to the inputs of the disconnected TIA stage 210, such as pulse signals or other short stimulus signals. These signals trigger oscillation in the TIA state 210, and the TIA stage 210 may be calibrated based at least in part on the frequency response of the TIA stage 210 to the oscillating signals. For example, calibration logic coupled to the baseband filter 200B (not shown in FIG. 2B for simplicity) may inject the oscillating signals. More particularly, a first differential pair of signals may be injected into the inputs Iₚ in and Iₙ in, and a second differential pair of signals may be injected into the inputs Qₚ in and Qₙ in. In some implementations, each injected signal may be a single pulse or another short stimulus signal. For example, the single pulse may be generated by coupling an input to ground, to a supply voltage, and then back to ground. In some aspects, the single pulse may vary in timing and polarity to represent the expected differential signaling between Iₚ in and Iₙ in (and Qₚ in and Qₙ in) and the quadrature relation between the I inputs and the Q inputs. The frequency response of the TIA stage 210 due to the injected signals may be determined, for example by comparing one or more outputs of the TIA stage 210 to the injected signals. This frequency response may be compared with a desired frequency response indicating that the TIA stage 210 is calibrated. Based on the comparison, values of the feedback variable capacitors 234, 238, 244, and 248 may be tuned so that the frequency response matches the desired frequency response. Because this calibration operation includes the amplifiers, resistors, and capacitors of the receiver filter, the calibration is more accurate than conventional techniques, and accounts for the non-idealities of the amplifiers of the TIA stage 210.

The PGA stage 220 may be calibrated similarly to TIA stage 210. That is, the feedback variable resistors 288, 290, 292, and 294 may be calibrated based on a bias resistance associated with the PGA stage 220. Next, signals, such as pulse or other short stimulus signals, may be provided to the inputs of the disconnected PGA stage 220. That is, a first differential pair of signals may be injected into the inputs 232 and 234, and a second pair of oscillating signals may be injected into the inputs 236 and 238. Similarly to the calibration of the TIA stage 210, the calibration logic coupled to the baseband filter 200B (not shown in FIG. 2B for simplicity) may inject these signals. The frequency response of the PGA stage 220 due to the injected signals may be determined, for example by comparing one or more outputs of the PGA stage 220 to the injected signals. This frequency response may be compared with a calibration frequency response indicating that the PGA stage 220 is calibrated. Based on the comparison, values of the feedback variable capacitors 270, 274, 280, and 280 may be tunes so that the frequency response matches the calibration frequency response. Because this calibration operation includes the amplifiers, resistors, and capacitors of the receiver filter, the calibration is more accurate than conventional techniques, and accounts for the non-idealities of the amplifiers of the PGA stage 220.

One potential complication when calibrating the PGA stage 220 which may not be present when calibrating the TIA stage 210 is that the op amp frequency of the fully differential amplifiers 268 and 278 may affect the oscillation frequency of the PGA stage 220. Thus, the effect on the frequency response of changing the capacitances of the feedback variable capacitors 270, 274, 280, and 284 may be different than the effect on the filter response. In order to reduce these effects, and accurately calibrate the PGA stage 220, it may be desirable to reduce the frequency of oscillation of the PGA stage 220 in response to the injected oscillating signals, in order to avoid the poles of the op amps of the PGA stage 220 during calibration operations. In some aspects, this oscillation frequency may be reduced by providing additional crossover resistance during the calibration operations. That is, during calibration, the values of the crossover variable resistors may be increased beyond what is required based on the bias resistance. For example, the feedback variable resistance may be added to the crossover variable resistance while the oscillating signals are injected into the PGA stage 220. More particularly, during the injection of the signals to initiate oscillation, the feedback variable resistor 272 may be placed in series with the crossover variable resistor 292, the feedback variable resistor 276 may be placed in series with the crossover variable resistor 294, the feedback variable resistor 282 may be placed in series with the crossover variable resistor 290, and the feedback variable resistor 286 may be placed in series with the crossover variable resistor 288. The values of the feedback variable capacitors of the PGA stage 220 may then be calibrated as discussed above.

In some aspects, similar techniques may be used for avoiding poles of the op amps of the TIA stage 210 by reducing the frequency of oscillation of the TIA stage 210 in response to injected oscillating signals during calibration operations. Similar to the techniques described for the PGA stage 220, the oscillation frequency of the TIA stage 210 may be reduced by providing additional crossover resistance during the calibration operations for the TIA stage 210. For example, the additional crossover resistance may be provided while the oscillating signals are injected into the TIA stage 210 by placing the feedback variable resistor 236 in series with the crossover variable resistor 256, and similarly placing the feedback variable resistor 240 in series with the crossover variable resistor 258, placing the feedback variable resistor 246 in series with the crossover variable resistor 254, and placing the feedback variable resistor 250 in series with the crossover variable resistor 252. The values of the feedback variable capacitors of the TIA stage 210 may then be calibrated as discussed above.

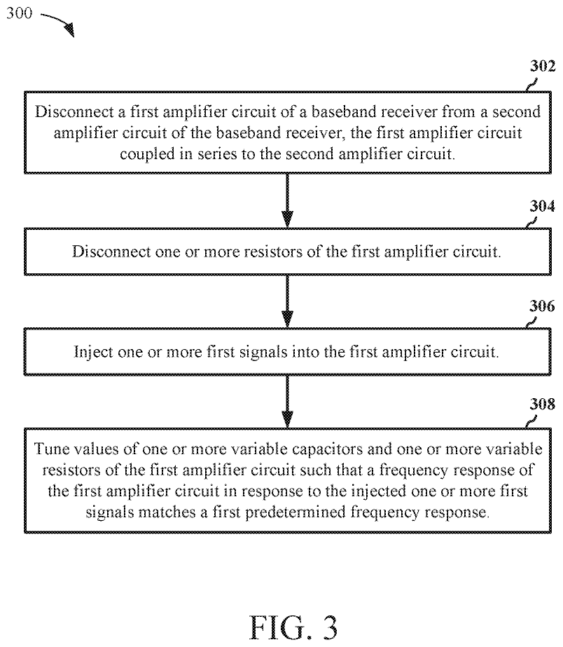

FIG. 3 shows an illustrative flow chart depicting an example operation 300 for calibrating a baseband receiver, according to some implementations. The example operation 300 may be performed by one or more processors of a computing device including or coupled to a receiver circuit such as the receiver circuit 100 of FIG. 1, or by one or more processors of a computing device including or coupled to a baseband filter such as the baseband filter 200A and 200B of FIGS. 2A-2B. It is to be understood that the example operation 300 may be performed by any suitable systems, computers, or servers.

At block 302, the receiver circuit 100 disconnects a first amplifier circuit of the baseband receiver from a second amplifier circuit of the baseband receiver, where the first amplifier circuit is coupled in series to the second amplifier circuit. At block 304, the receiver circuit 100 disconnects one or more resistors of the first amplifier circuit. At block 306, the receiver circuit 100 injects one or more first signals into the first amplifier circuit. At block 308, the receiver circuit 100 tunes values of one or more variable capacitors and one or more variable resistors of the first amplifier circuit such that a frequency response of the first amplifier circuit in response to the injected one or more first signals matches a first predetermined frequency response.

In some aspects, the first amplifier circuit includes a first fully differential amplifier having a first fully differential amplifier and a second fully differential amplifier, the first fully differential amplifier comprising a first input terminal, a second input terminal, a first output terminal, and a second output terminal, and the second fully differential amplifier comprising a third input terminal, a fourth input terminal, a third output terminal, and a fourth output terminal, wherein the first input terminal is coupled to the third output terminal via a first variable resistor, the second input terminal is coupled to the fourth output terminal via a second variable resistor; the third input terminal is coupled to the first output terminal via a third variable resistor, and the fourth input terminal is coupled to the second output terminal via a fourth variable resistor.

In some aspects, the one or more first signals include a first pair of oscillating signals injected into the first and second input terminals, and a second pair of oscillating signals injected into the third and the fourth input terminals.

In some aspects, disconnecting the one or more resistors of the first amplifier circuit includes disconnecting a fifth variable resistor coupling the first input terminal to the first output terminal, disconnecting a sixth variable resistor coupling the second input terminal to the second output terminal, disconnecting a seventh variable resistor coupling the third input terminal to the third output terminal, and disconnecting an eighth variable resistor coupling the fourth input terminal to the fourth output terminal.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

In the foregoing specification, embodiments have been described with reference to specific examples thereof. It will, however, be evident that various modifications and changes may be made thereto without departing from the broader scope of the disclosure as set forth in the appended claims. The specification and drawings are, accordingly, to be regarded in an illustrative sense rather than a restrictive sense.

What is claimed is:

1. A baseband receiver, comprising:
a first amplifier stage to receive one or more input signals and generate one or more intermediate signals responsive to the one or more input signals and based at least in part on one or more amplifiers, one or more capacitors, and one or more resistors of the first amplifier stage;
a second amplifier stage to receive the one or more intermediate signals and generate one or more output signals responsive to the one or more intermediate signals based at least in part on one or more amplifiers, one or more capacitors, and one or more resistors of the second amplifier stage; and
calibration logic configured to:
disconnect the first amplifier stage from the second amplifier stage; and
inject one or more first signals into at least the first amplifier stage and calibrate values of one or more resistors and one or more capacitors of the first amplifier stage based at least in part on a frequency response of the first amplifier stage to the injected one or more first signals.

2. The baseband receiver of claim 1, wherein:
the first amplifier stage comprises a first fully differential amplifier and a second fully differential amplifier, the first fully differential amplifier comprising a first input terminal, a second input terminal, a first output terminal, and a second output terminal, and the second fully differential amplifier comprising a third input terminal, a fourth input terminal, a third output terminal, and a fourth output terminal; and
the first input terminal is coupled to the third output terminal via a first variable resistor, the second input terminal is coupled to the fourth output terminal via a second variable resistor; the third input terminal is coupled to the first output terminal via a third variable resistor, and the fourth input terminal is coupled to the second output terminal via a fourth variable resistor.

3. The baseband receiver of claim 2, wherein the first input terminal is coupled to the first output terminal via a first capacitor, the second input terminal is coupled to the second output terminal via a second capacitor, the third input terminal is coupled to the third output terminal via a third capacitor, and the fourth input terminal is coupled to the fourth output terminal via a fourth capacitor.

4. The baseband receiver of claim 2, wherein the first input terminal is coupled to the first output terminal via a fifth variable resistor, the second input terminal is coupled to the second output terminal via a sixth variable resistor, the third input terminal is coupled to the third output terminal via a seventh variable resistor, and the fourth input terminal is coupled to the fourth output terminal via an eighth variable resistor.

5. The baseband receiver of claim 4, wherein the calibration logic is further configured to decouple the fifth variable resistor from the first input terminal, decouple the sixth variable resistor from the second input terminal, decouple the seventh variable resistor from the third input terminal, and decouple the eighth variable resistor from the fourth input terminal.

6. The baseband receiver of claim 2, wherein the one or more first signals include:
a first pair of stimulus inputs injected into the first and second input terminals; and
a second pair of stimulus inputs injected into the third and the fourth input terminals, where each stimulus input of the first pair and the second pair of stimulus inputs includes a single pulse.

7. The baseband receiver of claim 1, wherein the first amplifier stage comprises a transimpedance amplifier (TIA) stage, and the second amplifier stage comprises a programmable gain amplifier (PGA) stage.

8. The baseband receiver of claim 1, wherein the first amplifier stage is coupled to the second amplifier stage via one or more notch filters configured to attenuate signals at one or more signals associated with a sampling rate of one or more analog to digital converters (ADCs) coupled to the one or more output signals.

9. The baseband receiver of claim 2, wherein:
the second amplifier stage comprises a third fully differential amplifier and a fourth fully differential amplifier, the third fully differential amplifier comprising a fifth input terminal, a sixth input terminal, a fifth output terminal, and a sixth output terminal, and the fourth fully differential amplifier comprising a seventh input terminal, an eighth input terminal, a seventh output terminal, and an eighth output terminal; and
the fifth input terminal is coupled to the seventh output terminal via a ninth variable resistor, the sixth input terminal is coupled to the eighth output terminal via a tenth variable resistor; the seventh input terminal is coupled to the fifth output terminal via an eleventh variable resistor, and the eighth input terminal is coupled to the sixth output terminal via a twelfth variable resistor.

10. The baseband receiver of claim 9, wherein the fifth input terminal is coupled to the fifth output terminal via a fifth capacitor, the sixth input terminal is coupled to the sixth output terminal via a sixth capacitor, the seventh input terminal is coupled to the seventh output terminal via a seventh capacitor, and the eighth input terminal is coupled to the eighth output terminal via an eighth capacitor.

11. The baseband receiver of claim 9, wherein the fifth input terminal is coupled to the fifth output terminal via a thirteenth variable resistor, the sixth input terminal is coupled to the sixth output terminal via a fourteenth variable resistor, the seventh input terminal is coupled to the seventh output terminal via a fifteenth variable resistor, and the eighth input terminal is coupled to the eighth output terminal via a sixteenth variable resistor.

12. The baseband receiver of claim 11, wherein the calibration logic is further configured to decouple the thirteenth variable resistor from the fifth input terminal, decouple the fourteenth variable resistor from the sixth input terminal, decouple the fifteenth variable resistor from the seventh input terminal, and decouple the sixteenth variable resistor from the eighth input terminal.

13. The baseband receiver of claim 9, wherein the one or more first signals comprise a third pair of oscillating inputs injected into the fifth and sixth input terminals, and a fourth pair of oscillating inputs injected into the seventh and the eighth input terminals, where each oscillating input of the third pair and the fourth pair of oscillating inputs includes a single pulse.

14. The baseband receiver of claim 1, wherein the calibration logic is configured to adjust the values of the one or more resistors and one or more capacitors of the first amplifier stage so that the frequency response of the first amplifier stage to the injected one or more first signals matches a first predefined frequency response, the first predefined frequency response indicating that the first amplifier stage is properly calibrated.

15. The baseband receiver of claim 1, wherein at least one of the one or more first signals are injected into the second amplifier stage, and wherein the calibration logic is further configured to adjust values of one or more resistors and one or more capacitors of the second amplifier stage so that the frequency response of the second amplifier stage to the injected at least one of the one or more first signals matches a second predefined frequency response, the second predefined frequency response indicating that the second amplifier stage is properly calibrated.

16. A method of calibrating a baseband receiver, comprising:
disconnecting a first amplifier circuit of the baseband receiver from a second amplifier circuit of the baseband receiver, the first amplifier circuit coupled in series to the second amplifier circuit;
disconnecting one or more resistors of the first amplifier circuit;
injecting one or more first signals into the first amplifier circuit; and
tuning values of one or more variable resistors and one or more variable capacitors of the first amplifier circuit such that a frequency response of the first amplifier circuit in response to the injected one or more first signals matches a first predetermined frequency response.

17. The method of claim 16, wherein the first amplifier circuit comprises a first fully differential amplifier having a first fully differential amplifier and a second fully differential amplifier, the first fully differential amplifier comprising a first input terminal, a second input terminal, a first output terminal, and a second output terminal, and the second fully differential amplifier comprising a third input terminal, a fourth input terminal, a third output terminal, and a fourth output terminal;
wherein the first input terminal is coupled to the third output terminal via a first variable resistor, the second input terminal is coupled to the fourth output terminal via a second variable resistor; the third input terminal is coupled to the first output terminal via a third variable resistor, and the fourth input terminal is coupled to the second output terminal via a fourth variable resistor.

18. The method of claim 17, wherein one or more first signals comprise a first pair of stimulus inputs injected into the first and second input terminals, and a second pair of stimulus inputs injected into the third and the fourth input terminals, where each stimulus input of the first pair and the second pair of stimulus inputs includes a single pulse.

19. The method of claim 17, wherein disconnecting the one or more resistors of the first amplifier circuit comprises disconnecting a fifth variable resistor coupling the first input terminal to the first output terminal, disconnecting a sixth variable resistor coupling the second input terminal to the second output terminal, disconnecting a seventh variable resistor coupling the third input terminal to the third output terminal, and disconnecting an eighth variable resistor coupling the fourth input terminal to the fourth output terminal.

20. A baseband receiver, comprising:
a first amplifier stage comprising a first fully differential amplifier and a second fully differential amplifier;
a second amplifier stage coupled in series with the first amplifier stage; and
calibration logic for calibrating the first amplifier stage, the calibration logic configured to inject one or more first signals into inputs of the first amplifier stage and adjusting values of variable resistors and variable capacitors such that a frequency response of the first amplifier stage in response to the injected one or more first signals matches a first predetermined frequency response;
wherein each input of the first fully differential amplifier is coupled to a respective output of a second fully differential amplifier via a corresponding first crossover variable resistor, and wherein each input of the second fully differential amplifier is coupled to a respective output of the first fully differential amplifier via a corresponding second crossover variable resistor;
wherein each input of the first fully differential amplifier is coupled to a respective output of the first fully differential amplifier via a corresponding first feedback variable resistor and via a corresponding first feedback variable capacitor, and wherein each input of the second fully differential amplifier is coupled to a respective output of the second fully differential amplifier via a corresponding second feedback variable resistor and via a corresponding second feedback variable capacitor;
wherein the variable resistors and variable capacitors comprise the first crossover variable resistors, second crossover variable resistors, first feedback variable resistors, second feedback variable resistors, first feedback variable capacitors, and second feedback variable capacitors.
